(19) United States
(12) Patent Application Publication
(10) Pub. No.: US 2007/0237608 A1
(43) Pub. Date: Oct. 11, 2007

(54) CLUSTER DEVICE HAVING DUAL STRUCTURE

(75) Inventors: Geun-Ha JANG, Gyeonggi-do (KR); Chi-Wook Yu, Gyeonggi-do (KR)

Correspondence Address: MARGER JOHNSON & MCCOLLOM, P.C., 210 SW MORRISON STREET, SUITE 400, PORTLAND, OR, 97204, US

(73) Assignee: JUSUNG Engineering Co., Ltd, Gyeonggi-do (KR)

(21) Appl. No.: 11/758,754

(22) Filed: Jun. 6, 2007

Related U.S. Application Data
(63) Continuation of application No. 11/334,113, filed on Jan. 18, 2006.
(63) Continuation of application No. 10/754,199, filed on Jan. 9, 2004, now abandoned.

(30) Foreign Application Priority Data
Jan. 10, 2003 (KR) 2003-0001522
Jul. 15, 2003 (KR) 2003-0048344

(51) Int. Cl. H01L 21/677

(52) U.S. Cl. 414/217

(57) ABSTRACT

A cluster device having a dual structure includes: a substrate storage containing a plurality of substrates, the substrate storage having an ATM robot that moves said substrates; a first cluster including a first transfer chamber having a vacuum robot, a plurality of first process chambers connected to the first transfer chamber, and a first load lock chamber connected to both the substrate storage and the first transfer chamber; a second cluster including a second transfer chamber under the first transfer chamber, a plurality of second process chambers connected to the second transfer chamber, each of the plurality of second process chambers positioned between the two first process chambers, and a second load lock chamber connected to both the substrate storage and the second transfer chamber.

### CROSS REFERENCE TO RELATED APPLICATIONS

This application is a Continuation of U.S. patent application Ser. No. 11/334,113, filed on Jan. 18, 2006, now pending, which is a Continuation of U.S. patent application Ser. No. 10/754,199, filed on Jan. 9, 2004, now abandoned, which claims priority from Korean Patent Application Nos. 2003-0001522 and 2003-0048344 filed on Jan. 10, 2003 and Jul. 15, 2003, all of which are herein incorporated by reference in their entirety.

### BACKGROUND OF THE INVENTION

1. Field of the Invention

The present invention relates to an apparatus for manufacturing a thin film transistor liquid crystal display (TFT-LCD) device, and more particularly to a cluster device transferring substrates among modules of thin film processing.

2. Discussion of the Related Art

In general, since flat panel display devices are thin, light weight, and have low power consumption, they are commonly used in portable devices. Among the various types of flat panel display devices, liquid crystal display (LCD) devices are commonly used in laptop and desktop computer monitors because of their superior resolution, color image display, and display quality.

The LCD devices include upper and lower substrates having electrodes that are spaced apart from and face each other, and a liquid crystal material is interposed therebetween. Accordingly, when an electric field is induced to the liquid crystal material and when a voltage is supplied to the electrodes of the upper and lower substrates, an alignment direction of the liquid crystal molecules changes in accordance with the supplied voltage. By controlling the supplied voltage, the LCD devices provide various light transmittances in order to display image data.

The LCD devices are commonly incorporated in office automation (OA) devices and video equipment due to their light weight, thin design, and low power consumption. Among the different types of LCD devices, active matrix LCDs (AM-LCDs) have thin film transistors and pixel electrodes arranged in a matrix configuration and offer high resolution and superiority in displaying moving images. A typical AM-LCD panel has an upper substrate, a lower substrate, and a liquid crystal material layer interposed therebetween. The upper substrate, which is commonly referred to as a color filter substrate, includes a common electrode and color filters. The lower substrate, which is commonly referred to as an array substrate, includes switching elements, such as thin film transistors (TFTs), and pixel electrodes. The common and pixel electrodes produce electric fields between them to re-align the liquid crystal molecules.

When forming the array substrate and the color filter substrate, a lot of thin films are usually formed on and over glass substrates. At this time, a thin film deposition process, a photolithography process, a patterning process, a rinsing process and so on are required. The thin film deposition process forms a plurality of thin films, such as conductor films and insulator films, on and over the substrate. The photolithography and patterning processes removes or leaves some portions of the thin film using a photosensitive photoresist so as to pattern the thin films. The rinsing process removes residual impurities by way of washing and drying.

Each of the above-mentioned processes is conducted in a process chamber where a process atmosphere is optimized. Especially, a cluster that is a complex device is employed for the above-mentioned processes. The cluster includes plural process chambers that actually conduct the above-mentioned processes onto the substrates in a short time and a transfer chamber that transports the pre-processed substrates into the process chambers and collects the processed substrates from the process chambers. The process chambers of the cluster may provide with Plasma Enhanced Chemical Vapor Deposition (PECVD), Dry Etch, etc.

Meanwhile, the above-mentioned cluster providing the substrate with the thin film deposition process, the photolithography process, the etching process and the rinsing process can be applied to a process of manufacturing semiconductor devices.

FIG. 1 a schematic perspective view illustrating a cluster according to a related art, and FIG. 2 is a top exploded view illustrating the cluster of FIG. 1 in detail.

In FIGS. 1 and 2, a cluster 1 includes a transfer chamber 30 in the center and a load lock chamber 20 at one side of the transfer chamber 30. The transfer chamber 30 acts to transport and collect the substrate, and the load lock chamber 20 includes a slot where the substrate is loaded at process intervals. Additionally, the cluster 1 includes a plurality of process chambers 42, 43, 44, 45 and 46 that are connected to the transfer chamber 30 and where the desired processes are conducted onto the substrate. The cluster 1 also includes a warm-up chamber 50 that is connected to the transfer chamber 30 and where the substrate is preheated before the desired process in the process chambers 42, 43, 44, 45 and 46. Furthermore, a substrate storage 10 where a plurality of substrates are contained is joined to the load lock chamber 20.

The transfer chamber 30 of the cluster 1 transports a pre-processed substrate from the load lock chamber 20 to the warm-up chamber 50 and from the warm-up chamber 50 to the process chambers 42, 43, 44, 45 and 46. After the desired process is performed onto the substrate in the process chambers 42, 43, 44, 45 and 46, the substrate is collected by the transfer chamber 30 and moves back to the load lock chamber 20. Thus, the transfer chamber 30 acts as a temporary warehouse or a passageway.

FIG. 3 is a cross sectional view of a load lock chamber for use in the cluster according to a related art. In FIG. 3, the load lock chamber 20 can be divided in an upper load lock chamber 20a and a lower load lock chamber 20b. Each of the upper and lower load lock chambers 20a and 20b can have first and second slots 24 and 25 where the substrates are loaded. Doors 22 and 26 are located in the left and right sides of the upper and lower load lock chambers 20a and 20b. Each slot 24 or 25 includes supporting pins 29 that prevents the loaded substrate from directly contacting the slot 24 and 25. Driving cylinders 28 installed outsides the load lock chamber move the second slots 25 in up-and-down directions.

In the cluster 1 having the above-mentioned structure, the substrate is transferred in accordance with the following order. Hereinafter, it is assumed that the substrate is loaded in the upper load lock chamber 20a.

First of all, the substrate contained in the substrate storage 10 is moved into the load lock chamber 20 by an atmosphere (ATM) robot 12 (see FIG. 2), and then the substrate is mounted on the first slot 24 of the upper load lock chamber 20a. At this time, the second slot 25 does not support any substrate in order to receive the processed substrate from the transfer chamber 30. At the time when the substrate is carried to the load lock chamber 20, the load lock chamber 20 has the atmospheric pressure. Namely, the first door 22 opens and the second door 26 closes, when the substrate is mounted on the first slot 24.

After the substrate is loaded on the first slot 24, the first door 22 closes and then a vacuum pump (not shown) makes the inside of the load lock chamber 20 vacuous. Thereafter the second door 26 opens when the inside of the load lock chamber 20 becomes vacuous or when the inside of the load lock chamber 20 has the same pressure as that of the transfer chamber 30 or the process chambers 42, 43, 44, 45 and 46. After that, a vacuum robot 32 installed in the transfer chamber 30 takes the processed substrate from the process chamber 42, 43, 44, 45 or 46 onto the empty second slot 25, and moves the substrate mounted on the first slot 24 into the warm-up chamber 50.

The substrate preheated in the warm-up chamber 50 is transported into one of the process chambers 42, 43, 44, 45 and 46 by the vacuum robot 32 so that the thin film deposition process is conducted onto the substrate. The thin film deposition process can be (lone only in one process chamber or through several process chambers depending on what kind of thin film is formed.

After the thin film deposition in the process chambers 42, 43, 44, 45 and 46, the vacuum robot 32 moves the processed substrate from the process chambers into the load lock chamber 20, especially on the second slot 25. Thereafter, the second door 26 closes, and the inside of the load lock chamber 20 is vented by N₂ and/or He gases in order to be equalized to the atmospheric pressure. At this time, there will be additional process that is cooling down the processed substrate using Ar and/or N₂ cooling gases.

After cooling down the processed substrate and equalizing the pressure, the first door 22 is open and the processed substrate is moved back into the substrate storage 10.

Meanwhile, although not illustrated in FIGS. 1 and 2, slot valves are installed in between the transfer chamber 30 and the warm-up chamber 50 and in between the transfer chamber 30 and the process chambers 42, 43, 44, 45 and 46. The slot valves open the desired process chamber when the substrate is carrying into the desired chamber for the desired process, and also the slot valves close the process chambers for conducting the desired process.

In these days, since the substrate becomes larger and larger, the cluster is also much enlarged. This causes the increase of the manufacturing cost and the maintenance fee. Thus, it is a matter of concern and interest to increase the throughput when forming the semiconductor and/or thin film devices using the high-priced enlarged cluster.

When using the cluster and load lock chamber shown in FIGS. 1-3 in the formation of the triple thin films (SiN_{X} layer, a-Si:H layer and n⁺a-Si:H layer), the throughput per unit time is 30 substrates. And when forming the single thin film (SiN_{X} layer) using the cluster and load lock chamber illustrated in FIGS. 1-3, the throughput per unit time is 45 to 50 substrates. In order to increase the throughput per unit time and decrease the unit cost, the cluster has to increase the number of the process chamber, but this causes the cluster to be larger and the large cluster occupies rather larger installation area or may decrease the productivity in terms of costs to investment.

Specially, the transfer chamber is recently made of aluminum or stainless steel. Thus, if the transfer chamber is made in big size in accordance with the larger substrate, the production costs will dramatically increase and it may be difficult to manufacture the cluster with the larger transfer chamber and larger process chambers.

According to the conventional process, it takes about 40 seconds for the load lock chamber to vent and cool down, and it also takes about 30 seconds to make the inside of the load lock chamber vacuous. Thus, these additional pre-processes thoroughly affect the throughput per unit time. To decrease the time for the pre-processes, a lot of efforts are attempted. Especially, the vacuum pumping speed increases, but this causes a water droplet because of the adiabatic expansion. Furthermore, if the vacuum pumping time is reduced in order to reduce the pre-processes time, there will be some problems of improperly exhausting a lot of particles that inflow into the load lock chamber when the substrate is loaded on the slot. Those water droplet and particles deteriorate and degrade the made thin film during the thin film deposition process. Moreover, if the substrate is rapidly cooling down in order to reduce the substrate cooling time, the thin film stability is largely diminished.

### SUMMARY OF THE INVENTION

Accordingly, the present invention is directed to a cluster for transferring wafers among modules of thin film processing, which substantially obviates one or more of the problems due to limitations and disadvantages of the related art.

An advantage of the present invention is to provide a cluster for transferring substrates, and a load lock chamber of the cluster, which enhances the thin film productivity.

Another advantage of the present invention is to provide a cluster for transferring substrates, which handles a large substrate in a single interior space constituted by two transfer chambers coupled to each other.

Another advantage of the present invention is to provide a cluster for transferring substrates, which increases the thin film reliability and decreases the manufacturing costs of thin films.

Additional features and advantages of the invention will be set forth in the description which follows, and in part will be apparent from the description, or may be learned by practice of the invention. The objectives and other advantages of the invention will be realized and attained by the structure particularly pointed out in the written description and claims hereof as well as the appended drawings.

In order to achieve the above object, the preferred embodiment of the present invention provides a cluster device having a dual structure includes: a substrate storage containing a plurality of substrates, the substrate storage having an ATM robot that moves the substrates; a first cluster including a first transfer chamber having a vacuum robot, a plurality of first process chambers connected to the first transfer chamber, and a first load lock chamber connected to both the substrate storage and the first transfer chamber; a second cluster including; a second transfer chamber under the first transfer chamber, a plurality of second process chambers connected to the second transfer chamber, each of the plurality of second process chambers positioned between the two first process chambers, and a second load lock chamber connected to both the substrate storage and the second transfer chamber.

According to the present invention, the first transfer chamber is formed of as one united body with the second transfer chamber and wherein the first and second transfer chambers have one interior space. The first and second transfer chambers are coupled and sealed by O-ring, and wherein the first and second transfer chambers have one interior space. Each of the first and second load lock chambers has at least three slots therein. The cluster device of the present invention further includes at least driving cylinder on outer bottom of each of the first and second load lock chambers, wherein the driving cylinder moves at least one of the slits. Each of the slits includes supporting pins on an upper surface thereof. The second transfer chamber includes an additional vacuum robot.

In another aspect, one of the pluralities of first and second process chambers is a warm-up chamber. Each of the first and second load lock chamber includes an inlet door and an outlet door at both sidewalls, respectively, facing the substrate storage and the transfer chamber. The second transfer chamber has the same shape and the first transfer chamber and is twisted about 45 degrees relative to the first transfer. Each of the second process chambers makes an angle of 45 degrees with adjacent one of the first process chambers. The first load lock chamber is positioned next to the second load lock chamber and makes an angle of 45 degrees with the second load lock chamber. In another aspect, a transfer chamber includes: a first transfer chamber body having at least one first opening for transferring a substrate; a second transfer chamber body having at least one second opening for transferring the substrate, the first and second transfer chamber bodies detachably coupled to each other so that inner spaces of the first and second transfer chamber bodies are connected to each other; and a first robot for transferring the substrate disposed in the inner spaces of the first and second transfer chamber bodies connected to each other.

The first and second transfer chamber bodies are detachably coupled to each other by an O-ring, and the first and second transfer chamber bodies are vertically arranged. The transfer chamber further includes a second robot in the inner spaces of the first and second transfer chamber bodies connected to each other, and the first and second robots are vertically arranged. Each of the first and second transfer chamber bodies is coupled to at least one chamber such that each of first and second openings faces the at least one chamber. A number of the at least one first opening is the same as a number of the at least one second opening. The first transfer chamber body includes a lid.

In another aspect, a transfer chamber includes: a first transfer chamber body having a first opening for transferring a substrate; a second transfer chamber body having a second opening for transferring the substrate, the first and second transfer chamber bodies detachably coupled to each other so that inner spaces of the first and second transfer chamber bodies are connected to each other to constitute a single interior space; and a first robot for transferring the substrate disposed in the single interior space.

In another aspect, a transfer chamber includes: a first transfer chamber body having a first opening for transferring a substrate; a second transfer chamber body having a second opening for transferring the substrate, the first and second transfer chamber bodies detachably coupled to each other; and a robot for transferring the substrate disposed in an interior space constituted by inner spaces of the first and second transfer chamber bodies kept connected to each other while the first and second transfer chamber bodies are coupled to each other.

In another aspect, a transfer chamber includes: a first transfer chamber body having a first opening for inputting a substrate into a first process chamber and outputting the substrate from the first process chamber on at least one surface thereof, the first transfer chamber body having a robot for transferring the substrate therein; and a second transfer chamber body having a second opening for inputting a substrate into a second process chamber and outputting the substrate from the second process chamber on at least one surface thereof, the first and second transfer chamber bodies detachably coupled to each other so that inner spaces of the first and second transfer chamber bodies are connected to each other, wherein the substrate is inputted and outputted through the second opening by the robot.

In another aspect, a cluster includes: a transfer chamber including first and second transfer chamber bodies having first and second openings, respectively, for transferring a substrate, the first and second transfer chamber bodies detachably coupled to each other so that inner spaces of the first and second transfer chamber bodies are connected to each other; a robot for transferring the substrate in the inner space of the first transfer chamber body; and at least one chamber coupled to the transfer chamber.

In another aspect, a cluster includes: a transfer chamber including first and second transfer chamber bodies having first and second openings, respectively, for transferring a substrate, the first and second transfer chamber bodies detachably coupled to each other so that inner spaces of the first and second transfer chamber bodies are connected to each other to constitute a single interior space; a robot for transferring the substrate in the inner space of the first transfer chamber body; a load lock chamber coupled to the first transfer chamber body; and a plurality of process chambers coupled to each of the first and second transfer chamber bodies.

In another aspect, a cluster includes: a transfer chamber including first and second transfer chamber bodies having first and second openings, respectively, for transferring a substrate, inner spaces of the first and second transfer chamber bodies kept connected to each other while the first and second transfer chamber bodies are detachably coupled to each other; a robot for transferring the substrate in the inner space of the first transfer chamber body; a load lock chamber coupled to the first transfer chamber body such that the first opening faces the load lock chamber; and a process chamber coupled to the transfer chamber such that the first and second openings face the process chamber.

In another aspect, a cluster includes: a transfer chamber including a first transfer chamber body having a first opening for inputting a substrate into a first process chamber and outputting the substrate from the first process chamber on at least one surface thereof and a second transfer chamber body having a second opening for inputting a substrate into a second process chamber and outputting the substrate from the second process chamber on at least one surface thereof, the first transfer chamber body having a robot for transferring the substrate therein, the first and second transfer chamber bodies detachably coupled to each other so that inner spaces of the first and second transfer chamber bodies are connected to each other, wherein the substrate is inputted and outputted through the second opening by the robot; and a load lock chamber coupled to the transfer chamber.

In another aspect, a method of transferring a substrate in a cluster includes: loading a substrate in a load lock chamber; evacuating the load lock chamber, a transfer chamber coupled to the load lock chamber and a process chamber coupled to the transfer chamber, the transfer chamber including first and second transfer chamber bodies having first and second openings, respectively, for transferring the substrate, the first and second transfer chamber bodies detachably coupled to each other so that inner spaces of the first and second transfer chamber bodies are connected to each other, the first transfer chamber body having a robot for transferring the substrate therein; transferring the substrate from the load lock chamber to the process chamber through the transfer chamber by the robot; performing a process for the substrate in the process chamber; and transferring the substrate from the process chamber to the load lock chamber through the transfer chamber by the robot.

It is to be understood that both the foregoing general description and the following detailed description are exemplary and explanatory and are intended to provide further explanation of the invention as claimed.

### BRIEF DESCRIPTION OF THE DRAWING

The accompanying drawings, which are included to provide a further understanding of the invention and are incorporated in and constitute a part of this specification, illustrate embodiments of the invention and together with the description serve to explain the principles of the invention.

In the drawings:

FIG. 1 a schematic perspective view illustrating a cluster according to a related art;

FIG. 2 is a top exploded view illustrating the cluster of FIG. 1 in detail;

FIG. 3 is a cross sectional view of a load lock chamber for use in the cluster according to a related art;

FIG. 4 a schematic perspective view illustrating a cluster according to a present invention;

FIG. 5 is a top exploded view illustrating the cluster of FIG. 4 in detail; and

FIG. 6 is a cross sectional view of one of load lock chambers for use in the cluster according to a present invention.

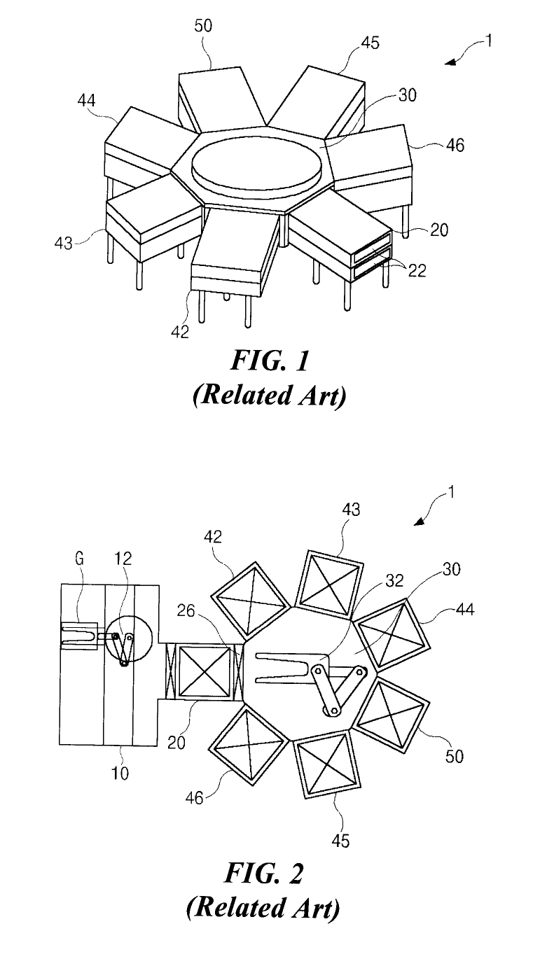

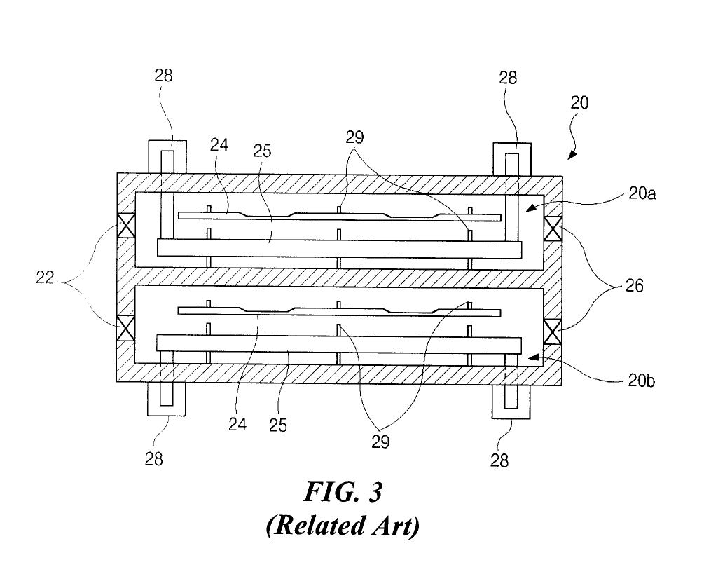

### DETAILED DESCRIPTION OF THE PREFERRED EMBODIMENTS

Reference will now be made in detail to the preferred embodiments of the present invention, examples of which are illustrated in the accompanying drawings. Wherever possible, the same reference numbers will be used throughout the drawings to refer to the same or like parts.

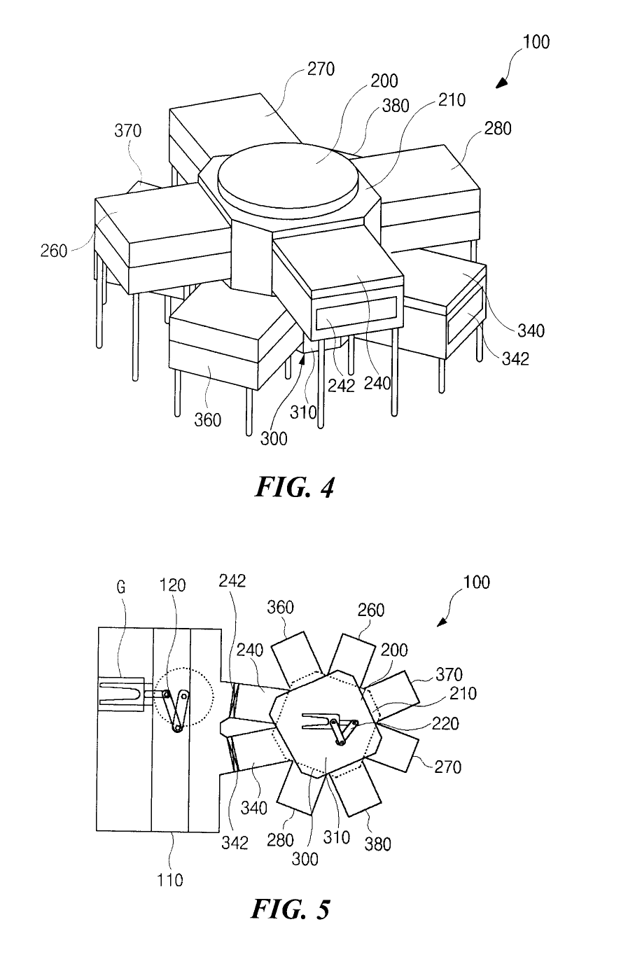

FIG. 4 a schematic perspective view illustrating a cluster according to a present invention, and FIG. 5 is a top exploded view illustrating the cluster of FIG. 4 in detail. In FIGS. 4 and 5, a cluster 100 is divided into a first cluster 200 and a second cluster 300 which are coupled in an up-and-down direction.

The first cluster 200 includes a first transfer chamber 210 in the center and a first load lock chamber 240 at one side of the first transfer chamber 210. The first transfer chamber 210 includes a vacuum robot 220 and acts to transport and collect the substrates, and the first load lock chamber 240 includes slots where the substrates are loaded at process intervals. Additionally, the cluster 100 includes a plurality of first process chambers 260, 270 and 280 that are connected to the first transfer chamber 210 and where the desired processes are conducted onto the substrate.

The second cluster 300 includes a second transfer chamber 310 under the first transfer chamber 210, and a second load lock chamber 340 at one side of the second transfer chamber 310. The second load lock chamber 340 is located next to the first load lock chamber 240. Additionally, the cluster 100 includes a plurality of second process chambers 360, 370 and 380 that are connected to the second transfer chamber 310 and where the desired processes are conducted into the substrate. Each of the second process chambers 360, 370 and 380 may be located in between two of the first process chambers and in between the first load lock chamber 240 and the first process chamber 260. The second transfer chamber 310 may be formed of as one united body with the first transfer chamber 210 so that the first and second transfer chamber 210 and 310 may have one interior space. Alternatively, the first and second transfer chambers 210 and 310 are formed separately, and then coupled and sealed by O-ring. The second transfer chamber 310 may have an additional vacuum robot (not shown) that is the same as the vacuum robot 220. As the first transfer chamber 210 does, the second transfer chamber 310 acts to transport and collect the substrates. The second load lock chamber 340 also includes slots where the substrates are loaded at process intervals.

As aforementioned, each of the first and second load lock chamber 240 and 340 has plural slots, for example, three slots. Furthermore, a substrate storage 110 that contains a plurality of substrates is joined to the first and second load lock chambers 240 and 340. And the first and second load lock chambers 240 and 340 have inlet doors 242 and 342, respectively, between the substrate storage 110 and the first and second lock chambers 240 and 340. Although not shown in FIGS. 4 and 5, each of the first and second load lock chambers 240 and 340 may have an outlet door between the transfer chamber and each of the first and second load lock chambers 240 and 340.

As shown in FIGS. 4 and 5, the first cluster 200 includes the first chambers 240, 260, 270 and 280 that are connected to the first transfer chamber 210 and met one another at right angles. And the second cluster 300 includes the second chambers 340, 360, 370 and 380 that are also connected to the second transfer chamber 310 and met one another at right angles. As shown in FIG. 5, the second transfer chamber 310 may be twisted about 45 degrees relative to the first transfer chamber 210. Each of the second chambers 340, 360, 370 and 380 may make an angle, for example 45 degrees, with adjacent one of the first chambers 240, 260 270 and 280. Namely, each of the second chambers 340, 360, 370 and 380 is located between two of the first chambers 240, 260, 270 and 280. However, there are no limitations in the number of the first and second chambers. In the present invention, one of the first and second process chambers 260, 270 280, 360, 370 and 380 is a warm-up chamber that preheats the substrate before the desired process in the process chambers 260, 270 280, 360, 370 and 380.

The first and second transfer chambers 210 and 310 transport pre-processed substrates from the first and load lock chambers 240 and 340 to the first and second process chambers 260 270 280, 360, 370 and 380. After the desired process is performed onto the substrate in the process chambers 260, 270 280, 360, 370 and 380, the processed substrate is collected and moves back to the first and second load lock chamber 240 and 340. Thus, the first and second transfer chambers 210 and 310 act as a temporary warehouse or a passageway.

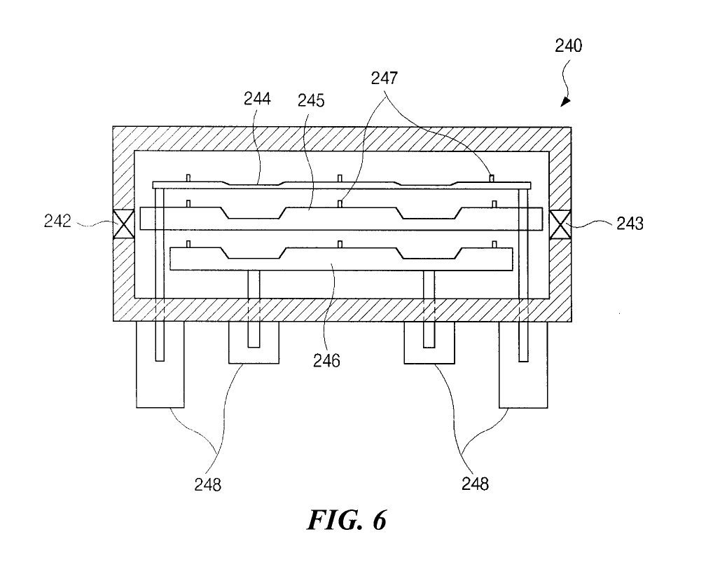

FIG. 6 is a cross sectional view of one of load lock chambers for use in the cluster according to the present invention. In FIG. 6, the first load lock chamber 240 is illustrated.

In FIG. 6, the first load lock chamber 240 has plural slots more than three, for example, first to third slots 244, 245 and 246, on which the substrates are loaded. Each of the first and third slots 244, 245 and 246 includes supporting pins 247 on an upper surface thereof. The supporting pins 247 prevent the loaded substrate from directly contacting the slots 244, 245 and 246. Driving cylinders 248 is installed on an outer bottom of the first load lock chamber 240 and move the slots 244, 245 and 246. The inlet door 242 is installed in the left wall that faces the substrate storage 110, and an outlet door 243 is installed in the right wall that faces the transfer chamber 210. In the present invention, the second load lock chamber 340 has the same structure and configuration as the first load lock chamber 240 of FIG. 6.

Although not shown in FIG. 6, the first load lock chamber 240 includes a gas exhaust pipe connected to a vacuum pump so that the inside of the first load lock chamber 240 can become a vacuum state, and the first load lock chamber 240 also includes a gas injection pipe connected to a gas container so that the inside of the first load lock chamber 240 can become an atmospheric state.

In the cluster 100 having the above-mentioned structure, the substrate is transferred in accordance with the following order. Hereinafter, it is assumed that the substrate is loaded in the first load lock chamber 240.

First of all, two pre-processed substrates are moved from the substrate storage 110 into the first load lock chamber 240 by an atmosphere (ATM) robot 120, and then the two pre-processed substrates are mounted on the first and second slots 244 and 245, respectively. Thereafter, the inlet door 242 closes, and the vacuum pump (not shown) is operated in order to make the inside of the load lock chamber 240 vacuous as much as the transfer and process chambers 210, 260, 270 and 280.

After vacuumizing, the outlet door 243 opens. Thereafter, the vacuum robot 220 takes the processed substrate out of the process chamber 260, 270 or 280, and puts the processed substrate on the empty third slot 246 of the load lock chamber 240. Also, the vacuum robot 220 transports one pre-processed substrate from the first slot 244 to the process chamber 260, 270 or 280, and then moves another processed substrate from the process chamber 260, 270 or 280 on the empty first slot 244. The vacuum robot 220 also moves the other pre-processed substrate, which is on the second slot 235, to one of the process chambers 260. 270 and 280. Accordingly, the two pre-processed substrates can change places with the two processed substrates.

After the substrate exchange, the two processed substrates are loaded on the first and third slots 244 and 246 of the load lock chamber 240. When the outlet door 243 closes, N₂ and/or He gases vent into the inside of the load lock chamber 240 in order to pressurize to the atmospheric pressure. At this time, there will be additional process that is cooling down the processed substrates using Ar and/or N₂ cooling gases. During the pressurizing and/or cooling processes, the first and third slots 244 and 246 where the processed substrates are loaded are approached closely to the second slot 245 where no substrate is loaded, so that the heat of the processed substrates can be transferred to the second slot 245. As described with reference to FIG. 6, each of the slots is movable by way of operating the driving cylinder 248.

After cooling down the processed substrates and pressurizing the inside of the load lock chamber 240, the inlet door 242 opens and the processed substrates are moved back into the substrate storage 110. Meanwhile, although not illustrated in FIGS. 4 and 5, slot valves may be installed in between the transfer chamber 210 and the process chambers 260, 270, and 280. The slot valve makes the desired process chamber open when the pre-processed or processed substrate is carrying into or out of that chamber. And also the slot valve closes for conducting the desired process in the desired process chamber.

According to the present invention shown in FIGS. 4-6, it takes about 60 seconds for the load lock chamber to vent and cool down and about 40 second to vacuumize the inside of the load lock chamber. As compared to the related art, the venting, cooling and vacuumizing time may be enlarged. However, the throughput per unit time increases. When forming the triple thin films (SiN_{X} layer, a-Si:H layer and n⁺a-Si:H layer), for example, using the present invention, the throughput per unit time is about 36 substrates. Also when forming the single thin film (SiN_{X} layer) using the cluster and load lock chamber of the present invention, the throughput per unit time is about 65 substrates.

In addition, since a large substrate is processed in a single interior spaced by two transfer chambers coupled to each other, a transfer chamber having a large volume is obtained without increase in cost. Accordingly, the present invention has an advantage in installation and transportation of a cluster for a large substrate.

The aforementioned substrate transporting system is also employed in the second cluster 300. Namely, the vacuum pumping and ventilation process for the first and second load lock chambers 240 and 340 and the substrate transportation in the chambers can be performed in both the first and second clusters 200 and 300 almost at the same time. Accordingly, since the two load lock chambers and the two transfer chambers are employed, respectively, the whole process time and steps can be reduced.

The cluster of the present invention can be applied to the liquid crystal display (LCD), semiconductor devices, plasma display panel (PDP) and organic electroluminescent display manufacture. Especially, the inventive cluster can be applied to the plasma enhanced chemical vapor deposition (PECVD) and the dry etcher.

According to the present invention, the cluster enlarges the productivity during the thin film deposition and patterning processes because the two transfer chambers are used. Additionally, since the cluster has the dual structure, it occupies smaller installation space. The present invention also has an advantage of lowering production costs. The cluster of the present invention has an advantage of handling a large substrate.

It will be apparent to those skilled in the art that various modifications and variation can be made in the present invention without departing from the spirit or scope of the invention. Thus, it is intended that the present invention covers the modifications and variations of this invention provided they come within the scope of the appended claims and their equivalents.

What is claimed is:

1. A transfer chamber comprising:
a first transfer chamber body having at least one first opening for transferring a substrate;
a second transfer chamber body having at least one second opening for transferring the substrate, the first and second transfer chamber bodies detachably coupled to each other so that inner spaces of the first and second transfer chamber bodies are connected to each other; and
a first robot for transferring the substrate disposed in the inner spaces of the first and second transfer chamber bodies connected to each other.

2. The transfer chamber according to claim 1, wherein the first and second transfer chamber bodies are detachably coupled to each other by an O-ring.

3. The transfer chamber according to claim 1, wherein the first and second transfer chamber bodies are vertically arranged.

4. The transfer chamber according to claim 1, further comprising a second robot in the inner spaces of the first and second transfer chamber bodies connected to each other.

5. The transfer chamber according to claim 4, wherein the first and second robots are vertically arranged.

6. The transfer chamber according to claim 1, wherein each of the first and second transfer chamber bodies is coupled to at least one chamber such that each of first and second openings faces the at least one chamber.

7. The transfer chamber according to claim 6, wherein a number of the at least one first opening is the same as a number of the at least one second opening.

8. The transfer chamber according to claim 1, wherein the first transfer chamber body includes a lid.

9. A transfer chamber comprising:
a first transfer chamber body having a first opening for transferring a substrate;
a second transfer chamber body having a second opening for transferring the substrate, the first and second transfer chamber bodies detachably coupled to each other so that inner spaces of the first and second transfer chamber bodies are connected to each other to constitute a single interior space; and
a first robot for transferring the substrate disposed in the single interior space.

10. The transfer chamber according to claim 9, wherein the first and second transfer chamber bodies are detachably coupled to each other by an O-ring.

11. The transfer chamber according to claim 9, further comprising a second robot for transferring the substrate disposed in the single interior space.

12. The transfer chamber according to claim 11, wherein the first and second robots are vertically arranged.

13. The transfer chamber according to claim 9, wherein each of the first and second transfer chamber bodies is coupled to at least one chamber such that each of the first and second openings faces the at least one chamber.

14. A transfer chamber comprising:
a first transfer chamber body having a first opening for transferring a substrate;
a second transfer chamber body having a second opening for transferring the substrate, the first and second transfer chamber bodies detachably coupled to each other; and
a robot for transferring the substrate disposed in an interior space constituted by inner spaces of the first and second transfer chamber bodies kept connected to each other while the first and second transfer chamber bodies are coupled.

15. The transfer chamber according to claim 14, wherein the first and second transfer chamber bodies are detachably coupled to each other by an O-ring.

16. The transfer chamber according to claim 14, wherein the first and second transfer chamber bodies are vertically arranged.

17. The transfer chamber according to claim 14, wherein each of the first and second transfer chamber bodies is coupled to at least one chamber such that each of the first and second openings faces the at least one chamber.

18. The transfer chamber comprising:
a first transfer chamber body having a first opening for inputting a substrate into a first process chamber and outputting the substrate from the first process chamber on at least one surface thereof, the first transfer chamber body having a robot for transferring the substrate therein; and
a second transfer chamber body having a second opening for inputting a substrate into a second process chamber and outputting the substrate from the second process chamber on at least one surface thereof, the first and second transfer chamber bodies detachably coupled to each other so that inner spaces of the first and second transfer chamber bodies are connected to each other,
wherein the substrate is inputted and outputted through the second opening by the robot.

19. The transfer chamber according to claim 18, wherein the first and second transfer chamber bodies are detachably coupled to each other by an O-ring.

20. The transfer chamber according to claim 18, wherein the first and second transfer chamber bodies are vertically arranged.

21. The transfer chamber according to claim 18, wherein each of the first and second transfer chamber bodies is coupled to at least one chamber such that each of the first and second openings faces the at least one chamber.

22. A cluster comprising:
a transfer chamber including first and second transfer chamber bodies having first and second openings, respectively, for transferring a substrate, the first and second transfer chamber bodies detachably coupled to each other so that inner spaces of the first and second transfer chamber bodies are connected to each other;
a robot for transferring the substrate in the inner space of the first transfer chamber body; and
at least one chamber coupled to the transfer chamber.

23. The cluster according to claim 22, wherein the first and second transfer chamber bodies are detachably coupled to each other by an O-ring.

24. The cluster according to claim 22, wherein the first and second transfer chamber bodies are vertically arranged.

25. The cluster according to claim 22, wherein each of the first and second transfer chamber bodies is coupled to the at least one chamber through a slot valve.

26. The cluster according to claim 25, wherein the at least one chamber includes one of a load lock chamber and a process chamber.

27. The cluster according to claim 25, wherein a number of the at least one chamber coupled to the first transfer chamber body is the same as a number of the at least one chamber coupled to the second transfer chamber body.

28. The cluster according to claim 26, wherein the first transfer chamber body and the load lock chamber are coupled to each other such that the first opening faces the load lock chamber.

29. A cluster comprising:
a transfer chamber including first and second transfer chamber bodies having first and second openings, respectively, for transferring a substrate, the first and second transfer chamber bodies detachably coupled to each other so that inner spaces of the first and second transfer chamber bodies are connected to each other to constitute a single interior space;
a robot for transferring the substrate in the inner space of the first transfer chamber body;
a load lock chamber coupled to the first transfer chamber body; and
a plurality of process chambers coupled to each of the first and second transfer chamber bodies.

30. The cluster according to claim 29, wherein the first and second transfer chamber bodies are detachably coupled to each other by an O-ring.

31. The cluster according to claim 30, wherein the first and second transfer chamber bodies are vertically arranged.

32. The cluster according to claim 30, wherein each of the first and second transfer chamber bodies is coupled to the plurality of process chambers through a slot valve.

33. A cluster comprising:
a transfer chamber including first and second transfer chamber bodies having first and second openings, respectively, for transferring a substrate, inner spaces of the first and second transfer chamber bodies kept connected to each other while the first and second transfer chamber bodies are detachably coupled to each other;
a robot for transferring the substrate in the inner space of the first transfer chamber body:
a load lock chamber coupled to the first transfer chamber body such that the first opening faces the load lock chamber; and
a process chamber coupled to the transfer chamber such that the first and second openings face the process chamber.

34. The cluster according to claim 33, wherein the first and second transfer chamber bodies are detachably coupled to each other by an O-ring.

35. The cluster according to claim 33, wherein the first and second transfer chamber bodies are vertically arranged.

36. A cluster comprising:
a transfer chamber including a first transfer chamber body having a first opening for inputting a substrate into a first process chamber and outputting the substrate from the first process chamber on at least one surface thereof and a second transfer chamber body having a second opening for inputting a substrate into a second process chamber and outputting the substrate from the second process chamber on at least one surface thereof, the first transfer chamber body having a robot for transferring the substrate therein, the first and second transfer chamber bodies detachably coupled to each other so that inner spaces of the first and second transfer chamber bodies are connected to each other, wherein the substrate is inputted and outputted through the second opening by the robot; and
a load lock chamber coupled to the transfer chamber.

37. The cluster according to claim 36, wherein the first and second transfer chamber bodies are detachably coupled to each other by an O-ring.

38. The cluster according to claim 36, wherein the load lock chamber and the first transfer chamber body are coupled to each other such that the first opening faces the load lock chamber.

39. The cluster according to claim 36, wherein the first and second transfer chamber bodies are vertically arranged.

40. A method of transferring a substrate in a cluster, comprising:
loading a substrate in a load lock chamber;
evacuating the load lock chamber, a transfer chamber coupled to the load lock chamber and a process chamber coupled to the transfer chamber, the transfer chamber including first and second transfer chamber bodies having first and second openings, respectively, for transferring the substrate, the first and second transfer chamber bodies detachably coupled to each other so that inner spaces of the first and second transfer chamber bodies are connected to each other, the first transfer chamber body having a robot for transferring the substrate therein;
transferring the substrate from the load lock chamber to the process chamber through the transfer chamber by the robot;
performing a process for the substrate in the process chamber; and
transferring the substrate from the process chamber to the load lock chamber through the transfer chamber by the robot.
